(19) United States
(12) Patent Application Publication
(10) Pub. No.: US 2026/0214953 A1
(43) Pub. Date: Jul. 23, 2026

(54) SEMICONDUCTOR DEVICE

(71) Applicant: Nuvoton Technology Corporation Japan, Kyoto (JP)

(72) Inventors: Naoaki OKADA, Kyoto (JP); Katsuyoshi JOKYU, Kyoto (JP); Yusuke KANDA, Kyoto (JP)

(21) Appl. No.: 19/035,268

(22) Filed: Jan. 23, 2025

(51) Int. Cl. H10D 62/17; H10D 30/66

(52) U.S. Cl. CPC H10D 62/393; H10D 30/668

(57) ABSTRACT

A semiconductor device includes a low-concentration impurity layer provided on a semiconductor substrate, a body region provided in the low-concentration impurity layer, gate trenches extending in a first direction parallel to the top surface of the semiconductor substrate and arranged at equal intervals in a second direction orthogonal to the first direction, and source regions and body contact regions arranged alternately one by one at first intervals in the first direction in each of mesa portions sandwiched between the gate trenches in the second direction. The top surface of each of the mesa portions includes first recessed portions that are recessed at second intervals in the first direction and whose bottom surfaces are at least partially in contact with the body contact regions or the body region, the second intervals being n times the first intervals, where n is an integer greater than or equal to one.

### FIELD

The present disclosure relates to a semiconductor device including a vertical metal-oxide-semiconductor (MOS) transistor.

### BACKGROUND

Semiconductor devices including vertical MOS transistors are conventionally known (see Patent Literature (PTL) 1 and 2, for example).

### CITATION LIST

### Patent Literature

PTL 1: Japanese Patent No. 3999225
PTL 2: Japanese Patent No. 7114824

### SUMMARY

### Technical Problem

In semiconductor devices including vertical MOS transistors, improvement is needed in resistance to area of safe operation (ASO) breakdown.

In view of this, an objective of the present disclosure is to provide a semiconductor device including a vertical MOS transistor and capable of improving resistance to ASO breakdown.

### Solution to Problem

A semiconductor device according to one aspect of the present disclosure includes: a vertical metal-oxide-semiconductor (MOS) transistor; a semiconductor substrate of a first conductivity type containing a first concentration of an impurity; a low-concentration impurity layer of the first conductivity type that is provided above and is in contact with the semiconductor substrate, and contains a second concentration of an impurity, the second concentration being lower than the first concentration; a body region of a second conductivity type that is provided in the low-concentration impurity layer and at the top surface of the low-concentration impurity layer, and contains a third concentration of an impurity, the second conductivity type being different from the first conductivity type; a plurality of gate trenches extending in a first direction parallel to the top surface of the semiconductor substrate, and arranged at equal intervals in a second direction, the plurality of gate trenches penetrating the body region from the top surface of the low-concentration impurity layer and reaching a portion of the low-concentration impurity layer, the second direction being orthogonal to the first direction and parallel to the top surface of the semiconductor substrate; a plurality of gate conductors provided in respective ones of the plurality of gate trenches; a plurality of source regions and a plurality of body contact regions arranged alternately one by one at first intervals in the first direction in each of a plurality of mesa portions sandwiched between the plurality of gate trenches in the second direction, the plurality of source regions being source regions of the first conductivity type provided in the mesa portion and at the top surface of the mesa portion, the plurality of body contact regions being body contact regions of the second conductivity type that are provided in the mesa portion and at the top surface of the mesa portion and contain a fourth concentration of an impurity, the fourth concentration being higher than the third concentration; and a source electrode of the vertical MOS transistor, in which the top surface of each of the plurality of mesa portions includes a plurality of first recessed portions that are recessed at second intervals in the first direction and whose insides are filled with the source electrode, the second intervals being n times the first intervals, where n is an integer greater than or equal to one, at least a portion of a bottom surface of each of the plurality of first recessed portions is in contact with one of the plurality of body contact regions or the body region, the entire bottom surfaces of the plurality of source regions are above the bottom surface of the body region and in contact with the body region, the entire bottom surfaces of the plurality of body contact regions are above the bottom surface of the body region and in contact with the body region, the entire top surfaces of the plurality of source regions are in contact with the source electrode, and the entire top surfaces of the plurality of body contact regions are in contact with the source electrode.

### Advantageous Effects

A semiconductor device according to one aspect of the present disclosure is a semiconductor device including a vertical MOS transistor and capable of improving resistance to ASO breakdown.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a plan view schematically illustrating an example of a structure of a semiconductor device according to an embodiment.

FIG. 2 is a cross-sectional view schematically illustrating an example of the structure of the semiconductor device according to the embodiment.

FIG. 3 is a circuit diagram of the semiconductor device according to the embodiment.

FIG. 4 is an enlarged cross-sectional perspective view schematically illustrating an example of a structure around gate trenches in the semiconductor device according to the embodiment.

FIG. 5 is an enlarged cross-sectional view schematically illustrating an example of the structure around the gate trenches in the semiconductor device according to the embodiment.

FIG. 6 is an enlarged plan view schematically illustrating an example of the structure around the gate trenches in the semiconductor device according to the embodiment.

FIG. 7 is an enlarged cross-sectional perspective view of a vertical MOS transistor according to the embodiment and illustrates a state in which a parasitic bipolar transistor and a parasitic capacitor are formed.

FIG. 8 is an enlarged cross-sectional view schematically illustrating an example of the structure around the gate trenches in the semiconductor device according to the embodiment.

FIG. 9 is an enlarged cross-sectional view schematically illustrating an example of the structure around the gate trenches in the semiconductor device according to the embodiment.

FIG. 10 is an enlarged cross-sectional view schematically illustrating an example of the structure around the gate trenches in the semiconductor device according to the embodiment.

FIG. 11 is an enlarged cross-sectional view schematically illustrating an example of the structure around the gate trenches in the semiconductor device according to the embodiment.

FIG. 12 is an enlarged cross-sectional view schematically illustrating an example of the structure around the gate trenches in the semiconductor device according to the embodiment.

FIG. 13 is an enlarged cross-sectional view schematically illustrating an example of the structure around the gate trenches in the semiconductor device according to the embodiment.

FIG. 14 is an enlarged cross-sectional view schematically illustrating an example of the structure around the gate trenches in the semiconductor device according to the embodiment.

FIG. 15 is an enlarged cross-sectional view schematically illustrating an example of the structure around the gate trenches in the semiconductor device according to the embodiment.

FIG. 16 is an enlarged cross-sectional view schematically illustrating an example of the structure around the gate trenches in the semiconductor device according to the embodiment.

FIG. 17 is an enlarged cross-sectional view schematically illustrating an example of the structure around the gate trenches in the semiconductor device according to the embodiment.

FIG. 18 is an enlarged cross-sectional view schematically illustrating an example of the structure around the gate trenches in the semiconductor device according to the embodiment.

FIG. 19 is an enlarged cross-sectional view schematically illustrating an example of the structure around the gate trenches in the semiconductor device according to the embodiment.

FIG. 20 is an enlarged cross-sectional perspective view schematically illustrating an example of the structure around the gate trenches in the semiconductor device according to the embodiment.

FIG. 21 is an enlarged plan view schematically illustrating an example of the structure around the gate trenches in the semiconductor device according to the embodiment.

FIG. 22 is an enlarged cross-sectional perspective view schematically illustrating an example of a structure around gate trenches in a conventional vertical MOS transistor.

FIG. 23 is an enlarged cross-sectional perspective view of the conventional vertical MOS transistor and illustrates a state in which a parasitic bipolar transistor and a parasitic capacitor are formed.

FIG. 24 is a schematic diagram for explaining the mechanism of the breakdown phenomenon of the conventional vertical MOS transistor.

### DESCRIPTION OF EMBODIMENT

### Circumstances Leading to One Aspect of the Present Disclosure

As described above, in semiconductor devices including vertical MOS transistors, improvement is needed in resistance to ASO breakdown.

Meanwhile, reduction in the conduction resistance of the vertical MOS transistor is needed.

Thus, the inventors diligently repeated experiments and analysis to achieve both the reduction in the conduction resistance of a vertical MOS transistor and the improvement in the resistance to ASO breakdown of the vertical MOS transistor in a semiconductor device including the vertical MOS transistor.

FIG. 22 is an enlarged cross-sectional perspective view illustrating a structure around gate trenches 517 in conventional vertical MOS transistor 500 including a plurality of gate trenches 517 arranged at equal intervals.

In FIG. 22, source electrode 551 of vertical MOS transistor 500 is illustrated as if it were transparent. However, in reality, source electrode 551 is not transparent, and the structure behind source electrode 551 is not directly visible through source electrode 551.

In FIG. 22, the Y-axis direction is an extending direction of gate trench 517, the Z-axis direction is opposite to the depth direction of gate trench 517, and the X-axis direction is a direction that is orthogonal to the Y-axis direction and the Z-axis direction and in which the plurality of gate trenches 517 are arranged at equal intervals.

Here, vertical MOS transistor 500 is described as an N-channel vertical MOS transistor.

As illustrated in FIG. 22, in vertical MOS transistor 500, gate conductor 515 extending in the extending direction of gate trench 517 and surrounded by gate oxide film 516 is provided inside gate trench 517. A plurality of source regions 514 and a plurality of body contact regions 513 are above body region 518 in the Z-axis direction and are arranged alternately one by one at predetermined intervals in the Y-axis direction. Then, the plurality of source regions 514 and the plurality of body contact regions 513 are in contact with and are connected to source electrode 551.

The inventors thought that in order to reduce the on resistance of vertical MOS transistor 500, it is effective to increase the density of gate trenches 517 by decreasing mesa width L×m that is the width between gate trenches 517 arranged at equal intervals in the X-axis direction.

However, the inventors noticed the phenomenon in which the resistance to ASO breakdown of vertical MOS transistor 500 is reduced by decreasing mesa width Lxm. Then, through the experiments and analysis, the inventors elucidated the mechanism of the phenomenon in which the resistance to the ASO breakdown of vertical MOS transistor 500 is reduced by decreasing mesa width Lxm.

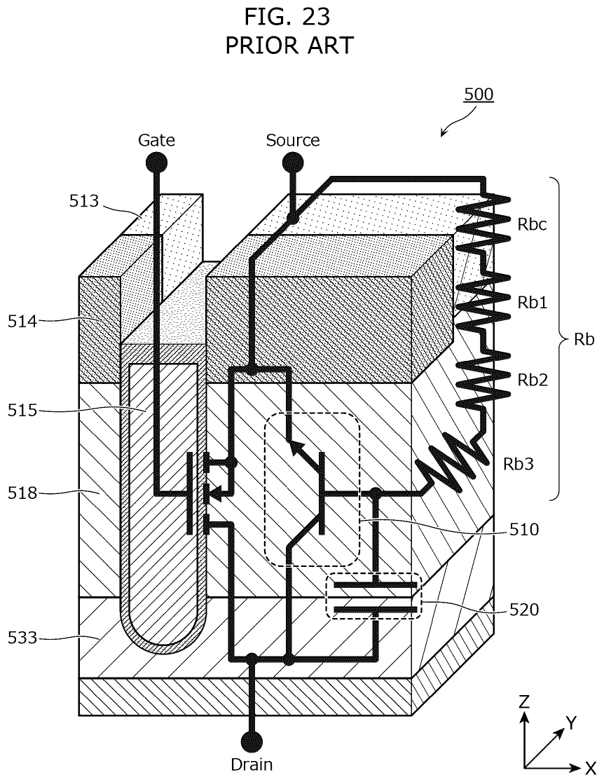

FIG. 23 is an enlarged cross-sectional perspective view of vertical MOS transistor 500 and illustrates a state in which a parasitic bipolar transistor and a parasitic capacitor are formed in vertical MOS transistor 500. However, in FIG. 23, illustration of source electrode 551 is omitted to avoid the figure becoming unnecessarily complex.

As illustrated in FIG. 23, in vertical MOS transistor 500, parasitic bipolar transistor 510 is formed which includes body region 518 as a base, low-concentration impurity layer 533 (hereinafter, also referred to as “drain region 533”) as a collector, and source region 514 as an emitter.

Moreover, as illustrated in FIG. 23, in vertical MOS transistor 500, parasitic capacitor 520 is formed on the bonding plane between body region 518 and drain region 533.

In FIG. 23, internal resistance Rb is internal resistance between the base of parasitic bipolar transistor 510 and source electrode 551 (not illustrated in FIG. 23, see FIG. 22).

As illustrated in FIG. 23, internal resistance Rb includes contact resistance Rbc between source electrode 551 and body contact region 513, internal resistance Rb1 in the Z-axis direction of body contact region 513, internal resistance Rb2 in the Z-axis direction of body region 518, and internal resistance Rb3 in the Y-axis direction of body region 518.

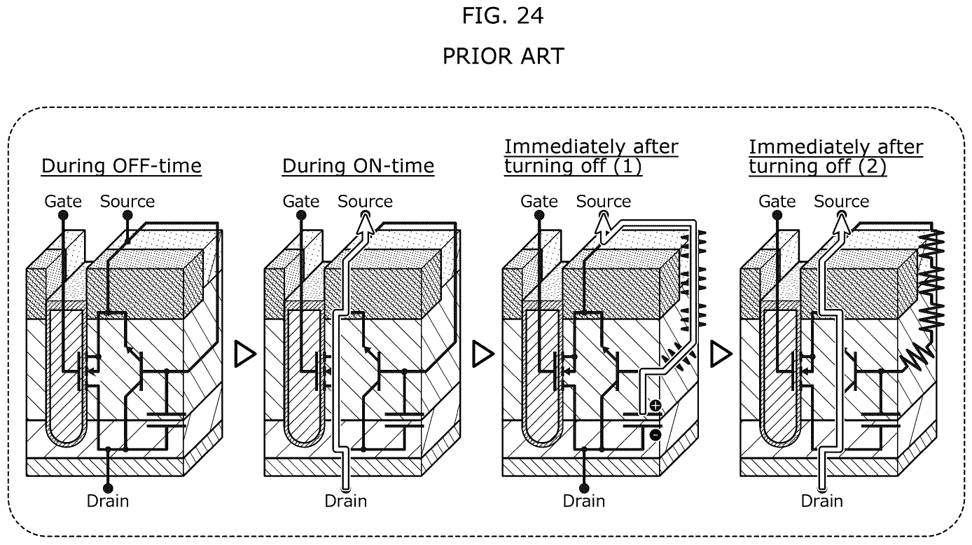

FIG. 24 is a schematic diagram for explaining the mechanism of the breakdown phenomenon of vertical MOS transistor 500.

As illustrated in FIG. 24, immediately after vertical MOS transistor 500 is switched from a conducting state to a non-conducting state, a current (hereinafter, also referred to as “a temporary current”) flows from drain region 533 to source electrode 551 (not illustrated in FIG. 24, see FIG. 22) via parasitic capacitor 520, body region 518, and body contact region 513 (see Immediately After Turning OFF (1)).

Here, when the product of current value Ioff [A] of the temporary current and resistance value Rb [Ω] of internal resistance Rb exceeds saturation voltage VBEsat [V] between the base and emitter of parasitic bipolar transistor 510, the emitter and collector of parasitic bipolar transistor 510 become conductive. As such, a large current flows from drain region 533 to source electrode 551 (see Immediately After Turning OFF (2)), which leads to the breakdown of vertical MOS transistor 500.

Here, internal resistance Rb increases with a decrease in mesa width Lxm.

Thus, when resistance value Rb [Ω] of internal resistance Rb is increased by decreasing mesa width Lxm, the product of current value Ioff [A] of the temporary current and resistance value Rb [Ω] of internal resistance Rb exceeds saturation voltage VBEsat [V] between the base and emitter of parasitic bipolar transistor 510 with only a smaller temporary current flow. As a result, the resistance to ASO breakdown of vertical MOS transistor 500 is reduced.

The inventors further repeated experiments and analysis on the basis of the mechanism in which the resistance to ASO breakdown of vertical MOS transistor 500 is reduced by decreasing mesa width Lxm. Then, the inventors acquired the following findings: even if mesa width Lxm is decreased, if internal resistance Rb1 in the Z-axis direction of body contact region 513 can be reduced, it is possible to reduce resistance value Rb [Ω] of internal resistance Rb, which enables improvement in the resistance to ASO breakdown of vertical MOS transistor 500.

Then, the inventors further repeated experiments and analysis on the basis of the findings and arrived at the following semiconductor device according to the present disclosure.

A semiconductor device according to one aspect of the present disclosure includes: a vertical metal-oxide-semiconductor (MOS) transistor; a semiconductor substrate of a first conductivity type containing a first concentration of an impurity; a low-concentration impurity layer of the first conductivity type that is provided above and is in contact with the semiconductor substrate, and contains a second concentration of an impurity, the second concentration being lower than the first concentration; a body region of a second conductivity type that is provided in the low-concentration impurity layer and at the top surface of the low-concentration impurity layer, and contains a third concentration of an impurity, the second conductivity type being different from the first conductivity type; a plurality of gate trenches extending in a first direction parallel to the top surface of the semiconductor substrate, and arranged at equal intervals in a second direction, the plurality of gate trenches penetrating the body region from the top surface of the low-concentration impurity layer and reaching a portion of the low-concentration impurity layer, the second direction being orthogonal to the first direction and parallel to the top surface of the semiconductor substrate; a plurality of gate conductors provided in respective ones of the plurality of gate trenches; a plurality of source regions and a plurality of body contact regions arranged alternately one by one at first intervals in the first direction in each of a plurality of mesa portions sandwiched between the plurality of gate trenches in the second direction, the plurality of source regions being source regions of the first conductivity type provided in the mesa portion and at the top surface of the mesa portion, the plurality of body contact regions being body contact regions of the second conductivity type that are provided in the mesa portion and at the top surface of the mesa portion and contain a fourth concentration of an impurity, the fourth concentration being higher than the third concentration; and a source electrode of the vertical MOS transistor, in which the top surface of each of the plurality of mesa portions includes a plurality of first recessed portions that are recessed at second intervals in the first direction and whose insides are filled with the source electrode, the second intervals being n times the first intervals, where n is an integer greater than or equal to one, at least a portion of a bottom surface of each of the plurality of first recessed portions is in contact with one of the plurality of body contact regions or the body region, the entire bottom surfaces of the plurality of source regions are above the bottom surface of the body region and in contact with the body region, the entire bottom surfaces of the plurality of body contact regions are above the bottom surface of the body region and in contact with the body region, the entire top surfaces of the plurality of source regions are in contact with the source electrode, and the entire top surfaces of the plurality of body contact regions are in contact with the source electrode.

In the semiconductor device configured as above, the top surface of a body contact region is recessed at each of the plurality of first recessed portions.

Thus, internal resistance Rb1 of body contact regions whose top surfaces are recessed at the plurality of first recessed portions is reduced.

Accordingly, the semiconductor device configured as above is a semiconductor device including the vertical MOS transistor and capable of improving resistance to ASO breakdown.

Moreover, in a plan view of the semiconductor substrate, each of the plurality of first recessed portions may be included inside one of the plurality of body contact regions, and the source electrode may not be in contact with any of the plurality of source regions inside the plurality of first recessed portions.

As such, the source electrode and the body contact region are in contact with each other at least on the side surface in the first direction among the side surfaces of each of the plurality of first recessed portions.

Thus, it is possible to increase the areas of contact between the source electrode and the body contact regions in the body contact regions whose top surfaces are recessed at the plurality of first recessed portions.

As such, contact resistance Rbc between the source electrode and the body contact regions in the body contact regions whose top surfaces are recessed at the plurality of first recessed portions is reduced.

Accordingly, in the semiconductor device configured as above, it is possible to further improve the resistance to ASO breakdown.

Moreover, the width of the first recessed portion in the second direction may be equal to the width of the plurality of mesa portions in the second direction.

As such, the plurality of first recessed portions can be relatively easily provided.

Moreover, the top surface of each of the plurality of mesa portions may further include a plurality of second recessed portions that are recessed at the second intervals in the first direction and whose insides are filled with the source electrode, and at least a portion of the bottom surface of each of the plurality of second recessed portions may be in contact with one of the plurality of body contact regions or the body region.

As such, the top surface of a body contact region is recessed at each of the plurality of second recessed portions.

Thus, internal resistance Rb1 of body contact regions whose top surfaces are recessed at the plurality of second recessed portions is reduced.

Accordingly, in the semiconductor device configured as above, it is possible to further improve the resistance to ASO breakdown.

Moreover, n may be one.

As such, the top surfaces of all the plurality of body contact regions are recessed.

Thus, internal resistance Rb1 of all the plurality of body contact regions is reduced.

Accordingly, in the semiconductor device configured as above, it is possible to further improve the resistance to ASO breakdown.

Moreover, the bottom surface of each of the plurality of first recessed portions may be above the bottom surface of the one of the plurality of body contact regions that includes the first recessed portion.

As such, the source electrode and the body contact region are in contact with each other on the bottom surface of each of the plurality of first recessed portions.

Thus, it is possible to increase the areas of contact between the source electrode and the body contact regions in the body contact regions whose top surfaces are recessed at the plurality of first recessed portions.

As such, contact resistance Rbc between the source electrode and the body contact regions in the body contact regions whose top surfaces are recessed at the plurality of first recessed portions is reduced.

Accordingly, in the semiconductor device configured as above, it is possible to further improve the resistance to ASO breakdown.

Moreover, the bottom surface of each of the plurality of first recessed portions may be below the bottom surface of the one of the plurality of body contact regions that includes the first recessed portion.

As such, internal resistance Rb2 in the Z-axis direction of the body region is reduced at each of the plurality of first recessed portions.

Accordingly, in the semiconductor device configured as above, it is possible to further improve the resistance to ASO breakdown.

Moreover, the impurity concentration of the body region may be higher in a portion including at least a part of portions in contact with the plurality of first recessed portions than in the remaining portion of the body region.

As such, contact resistance Rbc between the source electrode and the body region is reduced.

Accordingly, in the semiconductor device configured as above, it is possible to further improve the resistance to ASO breakdown.

Moreover, the bottom surface of each of the plurality of body contact regions may include a first bottom surface and a second bottom surface below the first bottom surface, and the bottom surface of each of the plurality of first recessed portions may be below the first bottom surface of the one of the plurality of body contact regions that includes the first recessed portion, and above the second bottom surface of the one of the plurality of body contact regions.

Moreover, the bottom surface of each of the plurality of first recessed portions may include a third bottom surface and a fourth bottom surface below the third bottom surface, and the third bottom surface of each of the plurality of first recessed portions may be above the bottom surface of the one of the plurality of body contact regions that includes the first recessed portion.

As such, it is possible to increase the areas of contact between the source electrode and the body contact regions in the body contact regions whose top surfaces are recessed at the plurality of first recessed portions.

Thus, it is possible to reduce contact resistance Rbc between the source electrode and the body contact regions in the body contact regions whose top surfaces are recessed at the plurality of first recessed portions.

Accordingly, in the semiconductor device configured as above, it is possible to further improve the resistance to ASO breakdown.

Moreover, the plurality of mesa potions may include a plurality of first mesa portions and a plurality of second mesa portions arranged alternately one by one in the second direction, and a positional phase in the first direction in which the plurality of source regions and the plurality of body contact regions are provided in each of the plurality of first mesa portions may differ from a positional phase in the first direction in which the plurality of source regions and the plurality of body contact regions are provided in each of the plurality of second mesa portions.

Hereinafter, a specific example of a semiconductor device according to one aspect of the present disclosure is described with reference to the figures. The embodiment described here indicates a specific example of the present disclosure. Accordingly, the numerical values, shapes, constituent elements, arrangement and connection of the constituent elements, as well as steps (processes), orders of the steps, and other details indicated in the following embodiment are merely examples, and do not intend to limit the present disclosure. Moreover, the figures are schematic illustrations and are not necessarily precise depictions. In the figures, substantially the same elements are assigned the same reference signs, and overlapping explanations are omitted or simplified.

### Embodiment

Hereinafter, a semiconductor device including a vertical MOS transistor according to an embodiment is described.

Here, a case where the number of vertical MOS transistors included in the semiconductor device according to the embodiment is one is described as an instance. However, the number of the vertical MOS transistors included in the semiconductor device according to the embodiment is not necessarily limited to one and may be two or more.

Moreover, here, the semiconductor device according to the embodiment is described as a chip size package (CSP) type semiconductor device that can be mounted face down. However, the semiconductor device according to the embodiment is not necessarily limited to a semiconductor device that can be mounted face down or a chip size package type semiconductor device.

### 1. Structure of Semiconductor Device

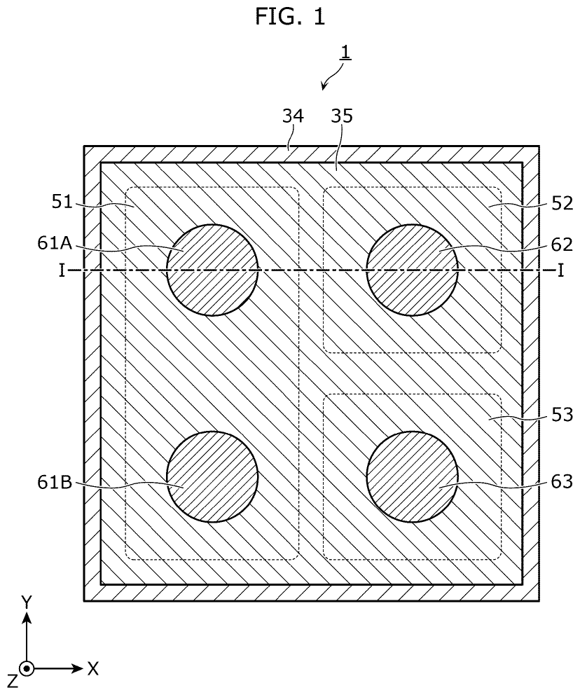

FIG. 1 is a plan view schematically illustrating an example of a structure of semiconductor device 1 according to Embodiment 1.

In FIG. 1, source electrode 51 (described later), drain electrode 52 (described later), and gate electrode 53 (described later) are indicated by the dashed lines as if the electrodes were directly visible from outside of semiconductor device 1. However, in reality, the electrodes are not directly visible from outside of semiconductor device 1.

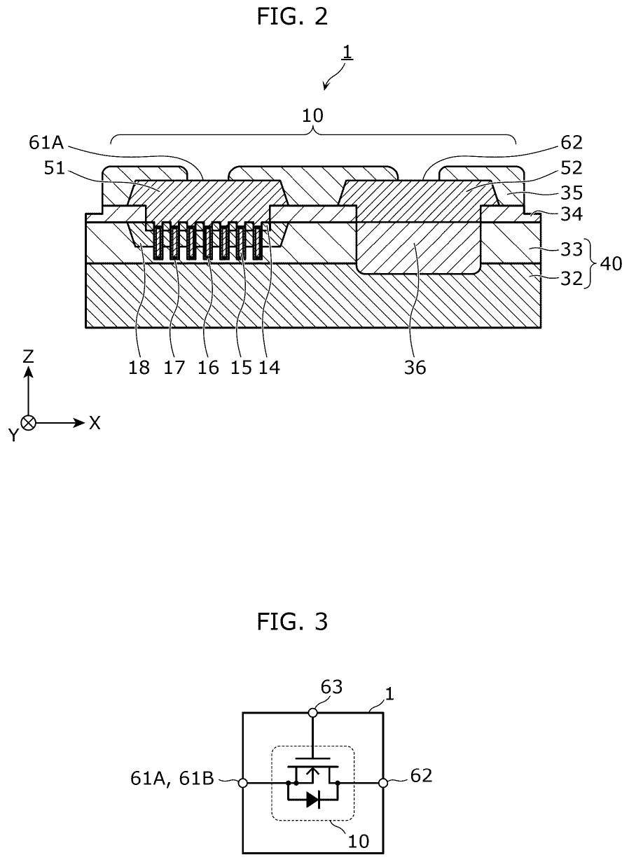

FIG. 2 is a cross-sectional view schematically illustrating an example of the structure of semiconductor device 1. FIG. 2 illustrates a cross section taken along I-I in FIG. 1.

FIG. 3 is a circuit diagram of semiconductor device 1.

As illustrated in FIGS. 1 to 3, semiconductor device 1 includes semiconductor layer 40, oxide film 34, protective film 35, source electrode 51, drain electrode 52, gate electrode 53, source pad 61A, source pad 61B, drain pad 62, gate pad 63, and vertical MOS transistor 10.

Semiconductor layer 40 is configured with semiconductor substrate 32 and low-concentration impurity layer 33 stacked on each other.

Semiconductor substrate 32 is made of silicon of a first conductivity type containing a first concentration of impurities.

Low-concentration impurity layer 33 is provided above and is in contact with semiconductor substrate 32. Low-concentration impurity layer 33 is made of silicon of the first conductivity type containing a second concentration of impurities, the second concentration being lower than the first concentration. For instance, low-concentration impurity layer 33 may be epitaxially grown on semiconductor substrate 32.

Typically, semiconductor conductivity types include the two conductivity types that are p-type and n-type. The first conductivity type may also be p-type or n-type. Here, for the convenience of explanation, the first conductivity type is described as n-type, and a second conductivity type, which is described later, is described as p-type. However, the first conductivity type may be p-type, and the second conductivity type may also be n-type.

Oxide film 34 is provided above and is in contact with low-concentration impurity layer 33.

Protective film 35 is a protective film covering the top surfaces of oxide film 34, source electrode 51, drain electrode 52, and gate electrode 53.

Protective film 35 includes an opening for exposing a portion of the top surface of source electrode 51 to outside protective film 35, an opening for exposing another portion of the top surface of source electrode 51 to outside protective film 35, an opening for exposing a portion of the top surface of drain electrode 52 to outside protective film 35, and an opening for exposing a portion of the top surface of gate electrode 53 to outside protective film 35.

The portions of the top surface of source electrode 51 are exposed to outside protective film 35 through the two openings in protective film 35. The portions of the top surface of source electrode 51 that are exposed to outside protective film 35 through the two openings in protective film 35 serve as source pad 61A and source pad 61B.

That is, source pad 61A is the portion of the top surface of source electrode 51 that is exposed to outside protective film 35 through one of the openings, and source pad 61B is the portion of the top surface of source electrode 51 that is exposed to outside protective film 35 through the other opening.

The portion of the top surface of drain electrode 52 is exposed to outside protective film 35 through the opening in protective film 35. The portion of the top surface of drain electrode 52 that is exposed to outside protective film 35 through the opening in protective film 35 serves as drain pad 62.

That is, drain pad 62 is the portion of the top surface of drain electrode 52 that is exposed to outside protective film 35 through the opening.

The portion of the top surface of gate electrode 53 is exposed to outside protective film 35 through the opening in protective film 35. The portion of the top surface of gate electrode 53 that is exposed to outside protective film 35 through the opening in protective film 35 serves as gate pad 63.

That is, gate pad 63 is the portion of the top surface of gate electrode 53 that is exposed to outside protective film 35 through the opening.

Body region 18 that contains a third concentration of impurities and is a body region of the second conductivity type different from the first conductivity type is provided in low-concentration impurity layer 33 and at the top surface thereof.

Moreover, a plurality of gate trenches 17 are provided in low-concentration impurity layer 33. The plurality of gate trenches 17 extend in a first direction (the Y-axis direction in FIGS. 1 and 2) parallel to the top surface of semiconductor substrate 32, and are arranged at equal intervals in a second direction (the X-axis direction in FIGS. 1 and 2) orthogonal to the first direction and parallel to the top surface of semiconductor substrate 32. The plurality of gate trenches 17 penetrate body region 18 from the top surface of low-concentration impurity layer 33 and reach a portion of low-concentration impurity layer 33.

Gate conductor 15 surrounded by gate oxide film 16 is provided in each of the plurality of gate trenches 17.

Moreover, drain lead-out region 36 of the first conductivity type penetrating low-concentration impurity layer 33 from the top surface of low-concentration impurity layer 33 and reaching semiconductor substrate 32 is provided in low-concentration impurity layer 33. Here, drain lead-out region 36 contains a fifth concentration of impurities, the fifth concentration being higher than the second concentration.

That is, semiconductor device 1 further includes body region 18, the plurality of gate trenches 17, the plurality of gate conductors 15, the plurality of gate oxide films 16, and drain lead-out region 36.

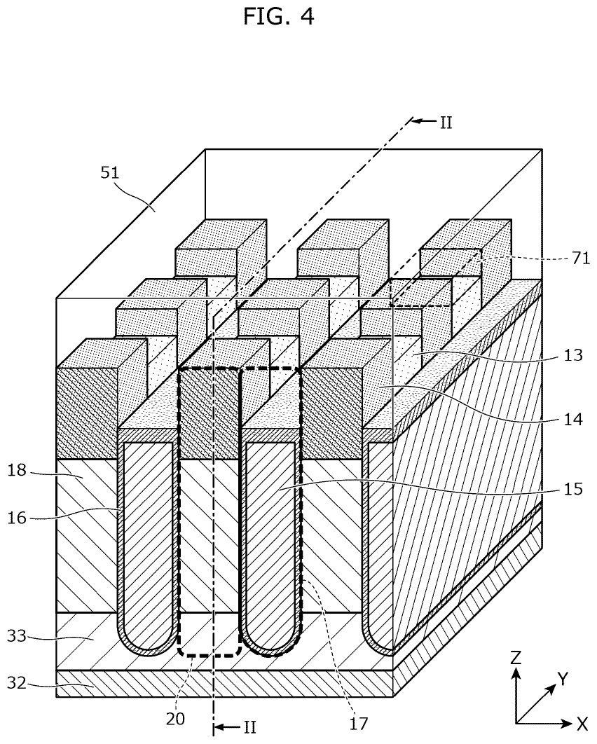

FIG. 4 is an enlarged cross-sectional perspective view schematically illustrating an example of a structure around gate trenches 17 in semiconductor device 1.

In FIG. 4, source electrode 51 is illustrated as if it were transparent. However, in reality, source electrode 51 is not transparent, and the structure behind source electrode 51 is not directly visible through source electrode 51.

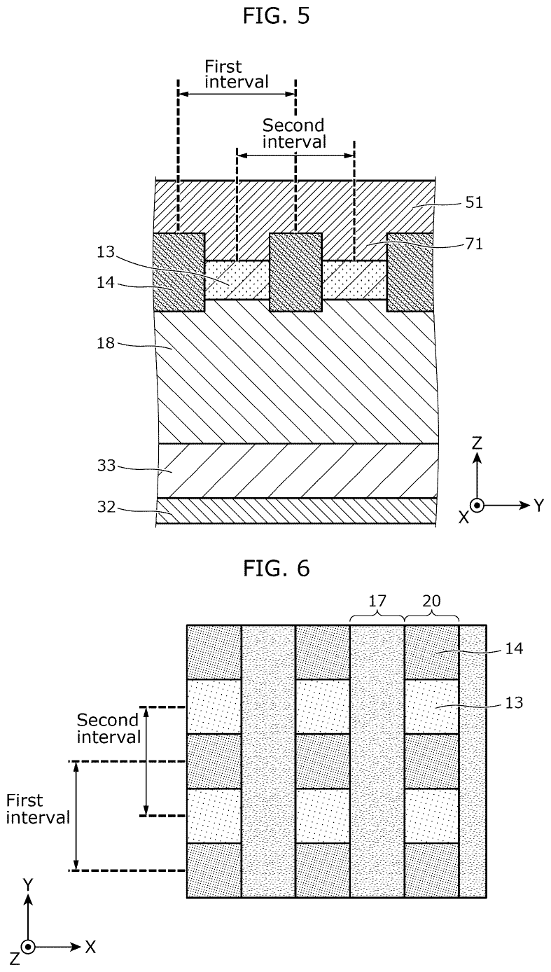

FIG. 5 is an enlarged cross-sectional view schematically illustrating an example of the structure around gate trenches 17 in semiconductor device 1. FIG. 5 illustrates a cross section taken along II-II in FIG. 4.

FIG. 6 is an enlarged plan view schematically illustrating an example of the structure around gate trenches 17 in semiconductor device 1.

In FIG. 6, illustration of source electrode 51 is omitted as if source electrode 51 were not present. However, in reality, source electrode 51 is present above the illustrated structure in the Z-axis direction in FIG. 6.

As illustrated in FIGS. 4 to 6, in low-concentration impurity layer 33, in each of a plurality of mesa portions 20 sandwiched between the plurality of gate trenches 17 in the second direction (the X-axis direction in FIGS. 4 to 6), a plurality of source regions 14 and a plurality of body contact regions 13 are arranged alternately one by one at first intervals in the first direction (the Y-axis direction in FIGS. 4 to 6). The plurality of source regions 14 are source regions of the first conductivity type provided in mesa portion 20 and at the top surface thereof. The plurality of body contact regions 13 are body contact regions of the second conductivity type that are provided in mesa portion 20 and at the top surface thereof and contain a fourth concentration of impurities, the fourth concertation being higher than the third concentration.

That is, semiconductor device 1 further includes the plurality of source regions 14 and the plurality of body contact regions 13.

As illustrated in FIGS. 4 to 6, the top surface of each of the plurality of mesa portions 20 includes a plurality of first recessed portions 71 that are recessed at second intervals in the first direction and whose insides are filled with source electrode 51. The second intervals are n times the first intervals, where n is an integer greater than or equal to one.

FIGS. 4 to 6 each illustrate a structure around gate trenches 17 when n is one. However, n is not necessarily limited to one and may be an integer greater than or equal to two.

Moreover, FIGS. 4 to 6 each illustrate the structure around gate trenches 17 when the width of first recessed portion 71 in the second direction is equal to the width of mesa portion 20 in the second direction. However, the width of first recessed portion 71 in the second direction is not necessarily limited to the same width as the width of mesa portion 20 in the second direction and may be less than the width of mesa portion 20 in the second direction.

However, when the width of first recessed portion 71 in the second direction is the same as the width of plurality of mesa portions 20 in the second direction, there is the advantage of being able to relatively easily provide the plurality of first recessed portions 71.

Moreover, FIGS. 4 to 6 each illustrate the structure around gate trenches 17 when the width of first recessed portion 71 in the first direction is equal to the width of body contact region 13 in the first direction. However, the width of first recessed portion 71 in the first direction is not necessarily limited to the same width as the width of body contact region 13 in the first direction and may be greater than or less than the width of body contact region 13 in the first direction.

As illustrated in FIGS. 4 to 6, at least a portion of the bottom surface of each of the plurality of first recessed portions 71 is in contact with one of the plurality of body contact regions 13 or body region 18.

FIGS. 4 to 6 each illustrate the structure around gate trenches 17 when the entire bottom surface of each of the plurality of first recessed portions 71 is in contact with one of the plurality of body contact regions 13. However, the configuration need not be limited to the configuration in which the entire bottom surface of each of the plurality of first recessed portions 71 is in contact with one of the plurality of body contact regions 13. The configuration may be the configuration in which at least a portion of the bottom surface of each of the plurality of first recessed portions 71 is in contact with body region 18. Alternatively, the configuration may be the configuration in which at least a portion of the bottom surface of each of the plurality of first recessed portions 71 is in contact with both one of the plurality of body contact regions 13 and body region 18.

Moreover, as illustrated in FIGS. 4 to 6, the entire bottom surfaces of the plurality of source regions 14 are above the bottom surface of body region 18 and in contact with body region 18. The entire bottom surfaces of the plurality of body contact regions 13 are above the bottom surface of body region 18 and in contact with body region 18. The entire top surfaces of the plurality of source regions 14 are in contact with source electrode 51. The entire top surfaces of the plurality of body contact regions 13 are in contact with source electrode 51.

With this configuration, semiconductor device 1 includes vertical MOS transistor 10.

As illustrated in FIGS. 2, 4, and 5, source electrode 51 is an electrode in contact with and is connected to the plurality of source regions 14 and the plurality of body contact regions 13. As such, source electrode 51 functions as the source electrode of vertical MOS transistor 10.

That is, source electrode 51 is the source electrode of vertical MOS transistor 10.

As a non-limiting example, source electrode 51 is made of, for example, one or more metals containing a metal whose main component is aluminum.

Drain electrode 52 is an electrode in contact with and is connected to drain lead-out region 36. As such, drain electrode 52 functions as the drain electrode of vertical MOS transistor 10.

That is, drain electrode 52 is the drain electrode of vertical MOS transistor 10.

As a non-limiting example, drain electrode 52 is made of, for example, one or more metals containing a metal whose main component is aluminum.

Gate electrode 53 is an electrode electrically connected to gate conductor 15. As such, gate electrode 53 functions as the gate electrode of vertical MOS transistor 10.

That is, gate electrode 53 is the gate electrode of vertical MOS transistor 10.

As a non-limiting example, gate electrode 53 is made of, for example, one or more metals containing a metal whose main component is aluminum.

### 2. Observation

In semiconductor device 1 configured as above, a parasitic bipolar transistor and a parasitic capacitor are formed in vertical MOS transistor 10.

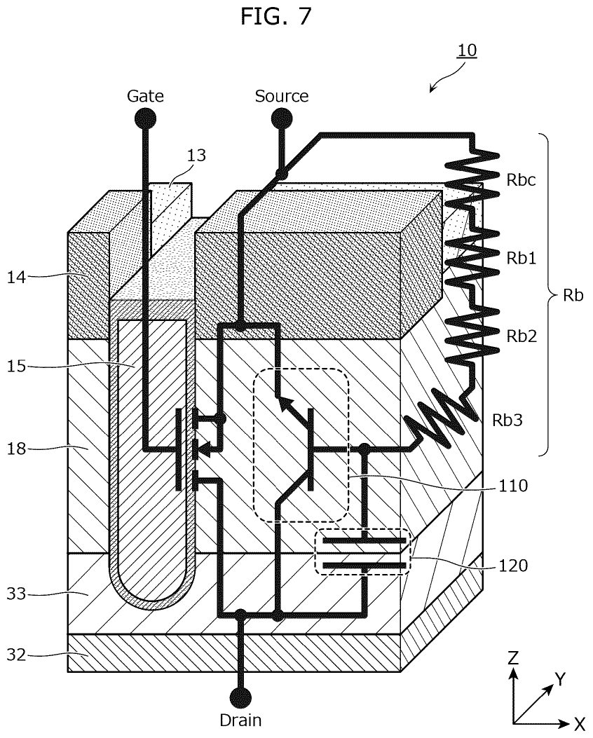

FIG. 7 is an enlarged cross-sectional perspective view of vertical MOS transistor 10 and illustrates a state in which a parasitic bipolar transistor and a parasitic capacitor are formed in vertical MOS transistor 10. However, in FIG. 7, illustration of source electrode 51 is omitted to avoid the figure becoming unnecessarily complex.

As illustrated in FIG. 7, in vertical MOS transistor 10, parasitic bipolar transistor 110 is formed which includes body region 18 as a base, low-concentration impurity layer 33 (hereinafter, also referred to as “drain region 33”) as a collector, and source region 14 as an emitter.

Moreover, as illustrated in FIG. 7, in vertical MOS transistor 10, parasitic capacitor 120 is formed on the bonding plane between body region 18 and drain region 33.

In FIG. 7, internal resistance Rb is internal resistance between the base of parasitic bipolar transistor 110 and source electrode 51 (not illustrated in FIG. 7, see FIG. 4, for example).

As illustrated in FIG. 7, internal resistance Rb includes contact resistance Rbc between source electrode 51 and body contact region 13, internal resistance Rb1 in the Z-axis direction of body contact region 13, internal resistance Rb2 in the Z-axis direction of body region 18, and internal resistance Rb3 in the Y-axis direction of body region 18.

As illustrated in FIGS. 4 and 5, in semiconductor device 1 configured as above, the top surface of body contact region 13 is recessed at each of the plurality of first recessed portions 71.

Thus, in semiconductor device 1 configured as above, internal resistance Rb1 of body contact regions 13 whose top surfaces are recessed at the plurality of first recessed portions 71 is reduced in comparison with a conventional semiconductor device without first recessed portions 71 (for example, a conventional semiconductor device including conventional vertical MOS transistor 500 illustrated in FIGS. 22 and 23).

Accordingly, semiconductor device 1 configured as above is a semiconductor device including vertical MOS transistor 10 and capable of improving resistance to ASO breakdown.

It should be noted that in the embodiment, it is described that an integer of n indicating the ratio of the second interval to the first interval is not necessarily limited to one and may be an integer greater than or equal to two. However, it is preferable that n be one.

When n is one, the top surfaces of all the plurality of body contact regions 13 are recessed.

Thus, internal resistance Rb1 of all the plurality of body contact regions 13 is reduced.

Accordingly, when n is one, it is possible to further improve the resistance to ASO breakdown.

It should be noted that in a plan view of semiconductor substrate 32, each of the plurality of first recessed portions 71 may be included inside one of the plurality of body contact regions 13, and source electrode 51 may not be in contact with any of the plurality of source regions 14 inside the plurality of first recessed portions 71.

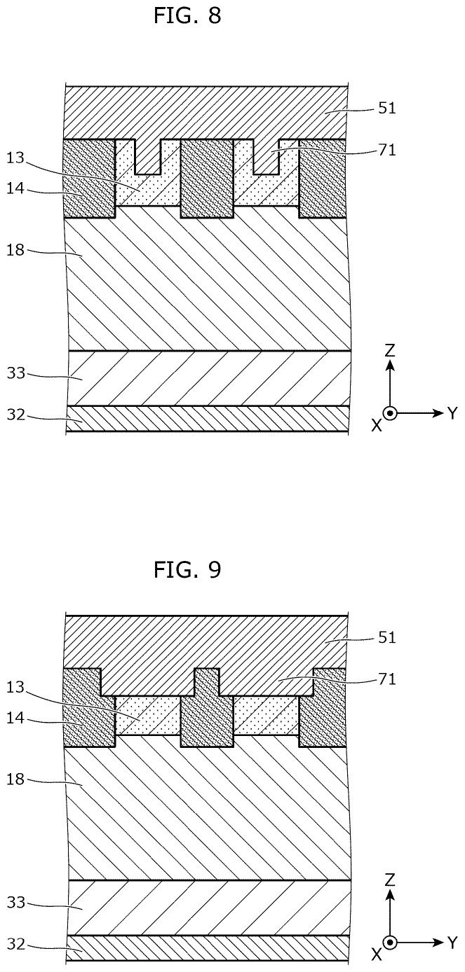

FIG. 8 is an enlarged cross-sectional view schematically illustrating an example of the structure around gate trenches 17 in semiconductor device 1 configured as above.

As such, source electrode 51 and body contact region 13 are in contact with each other at least on the side surface in the first direction among the side surfaces of each of the plurality of first recessed portions 71.

Thus, it is possible to increase the areas of contact between source electrode 51 and body contact regions 13 in body contact regions 13 whose top surfaces are recessed at the plurality of first recessed portions 71.

As such, contact resistance Rbc between source electrode 51 and body contact regions 13 in body contact regions 13 whose top surfaces are recessed at the plurality of first recessed portions 71 is reduced.

Accordingly, in semiconductor device 1 configured as above, it is possible to further improve the resistance to ASO breakdown.

It should be noted that in the plan view of semiconductor substrate 32, each of the plurality of first recessed portions 71 may include one of the plurality of body contact regions 13.

FIG. 9 is an enlarged cross-sectional view schematically illustrating an example of the structure around gate trenches 17 in semiconductor device 1 configured as above.

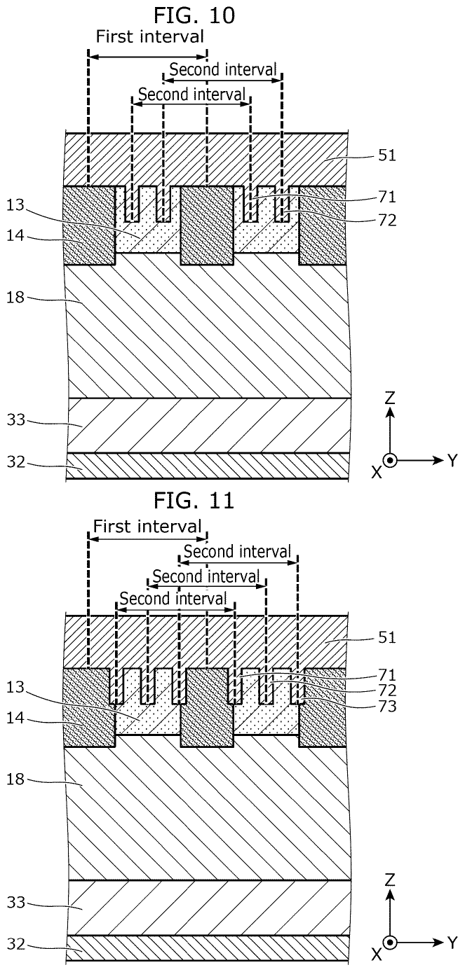

It should be noted that the top surface of each of the plurality of mesa portions 20 may further include a plurality of second recessed portions 72 (see FIG. 10 described later) that are recessed at the second intervals in the first direction and whose insides are filled with source electrode 51, and at least a portion of the bottom surface of each of the plurality of second recessed portions 72 may be in contact with one of the plurality of body contact regions 13 or body region 18.

FIG. 10 is an enlarged cross-sectional view schematically illustrating an example of the structure around gate trenches 17 in semiconductor device 1 configured as above.

As such, the top surface of body contact region 13 is recessed at each of the plurality of second recessed portions 72.

Thus, internal resistance Rb1 of body contact regions 13 whose top surfaces are recessed at the plurality of second recessed portions 72 is reduced.

Accordingly, in semiconductor device 1 configured as above, it is possible to further improve the resistance to ASO breakdown.

It should be noted that the top surface of each of the plurality of mesa portions 20 may further include a plurality of third to kth recessed portions 73 (see FIG. 11 described later) that are recessed at the second intervals in the first direction and whose insides are filled with source electrode 51, where k is an integer greater than or equal to zero, and at least a portion of the bottom surface of each of the plurality of third to kth recessed portions 73 may be in contact with one of the plurality of body contact regions 13 or body region 18.

FIG. 11 is an enlarged cross-sectional view schematically illustrating an example of the structure around gate trenches 17 in semiconductor device 1 configured as above when k is zero.

As such, the top surface of body contact region 13 is recessed at each of the plurality of third to kth recessed portions 73.

Thus, internal resistance Rb1 of body contact regions 13 whose top surfaces are recessed at the plurality of third to kth recessed portions 73 is reduced.

Accordingly, in semiconductor device 1 configured as above, it is possible to further improve the resistance to ASO breakdown.

It should be noted that semiconductor device 1 exemplified in FIGS. 5 and 8 to 11 has a structure in which the bottom surface of each of the plurality of first recessed portions 71 is above the bottom surface of the one of the plurality of body contact regions 13 that includes corresponding first recessed portion 71.

As such, source electrode 51 and body contact region 13 are in contact with each other on the bottom surface of each of the plurality of first recessed portions 71.

Thus, it is possible to increase the areas of contact between source electrode 51 and body contact regions 13 in body contact regions 13 whose top surfaces are recessed at the plurality of first recessed portions 71.

As such, contact resistance Rbc between source electrode 51 and body contact regions 13 in body contact regions 13 whose top surfaces are recessed at the plurality of first recessed portions 71 is reduced.

Accordingly, in semiconductor device 1 configured as above, it is possible to further improve the resistance to ASO breakdown.

By contrast, the bottom surface of each of the plurality of first recessed portions 71 may be below the bottom surface of the one of the plurality of body contact regions 13 that includes corresponding first recessed portion 71.

FIG. 12 is an enlarged cross-sectional view schematically illustrating an example of the structure around gate trenches 17 in semiconductor device 1 configured as above.

As such, internal resistance Rb2 in the Z-axis direction of body region 18 is reduced at each of the plurality of first recessed portions 71.

Accordingly, in semiconductor device 1 configured as above, it is possible to further improve the resistance to ASO breakdown.

It should be noted that the impurity concentration of body region 18 may be higher in a portion including at least a part of portions in contact with the plurality of first recessed portions 71 than in the remaining portion of body region 18.

As such, contact resistance Rbc between source electrode 51 and body region 18 is reduced.

Accordingly, in semiconductor device 1 configured as above, it is possible to further improve the resistance to ASO breakdown.

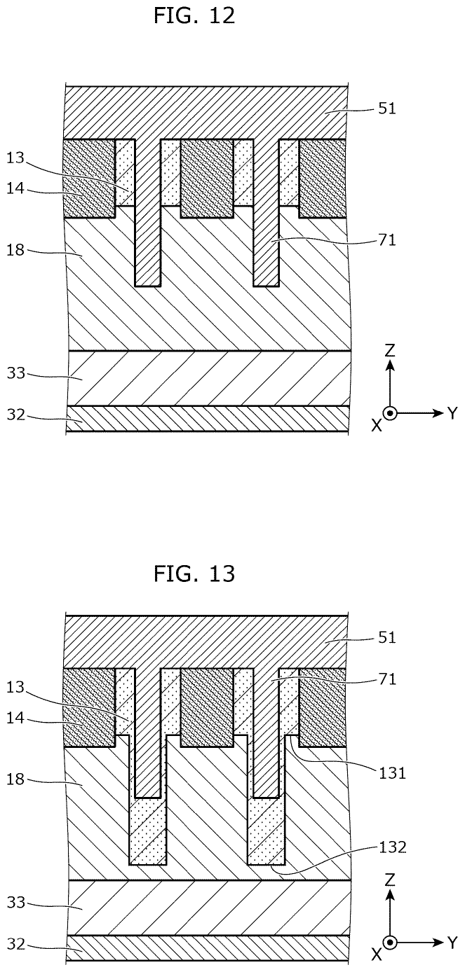

It should be noted that the bottom surface of each of the plurality of body contact regions 13 may include first bottom surface 131 (see FIG. 13 described later) and second bottom surface 132 (see FIG. 13 described later) below first bottom surface 131. The bottom surface of each of the plurality of first recessed portions 71 may be below first bottom surface 131 of the one of the plurality of body contact regions 13 that includes corresponding first recessed portion 71, and above second bottom surface 132 of the one of the plurality of body contact regions 13.

FIG. 13 is an enlarged cross-sectional view schematically illustrating an example of the structure around gate trenches 17 in semiconductor device 1 configured as above.

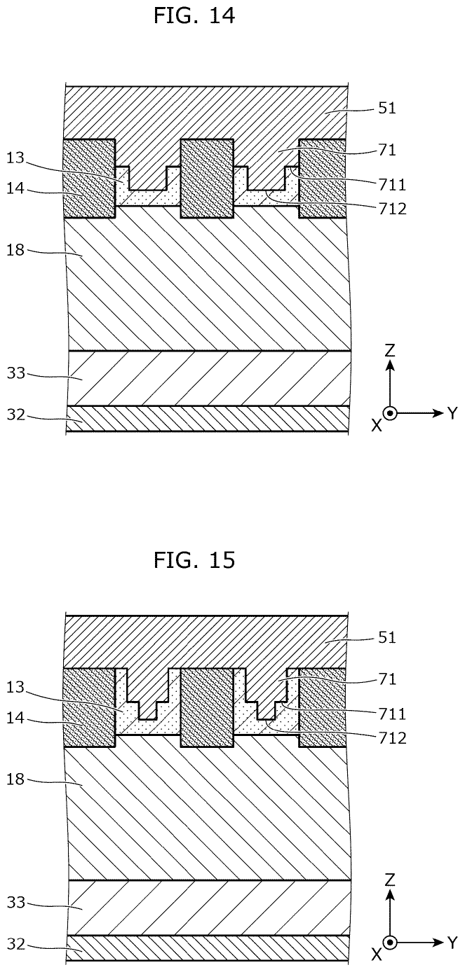

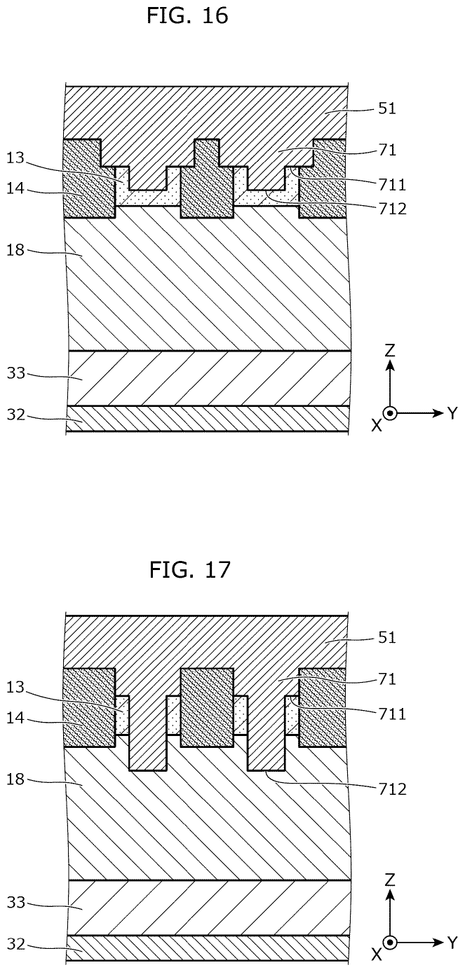

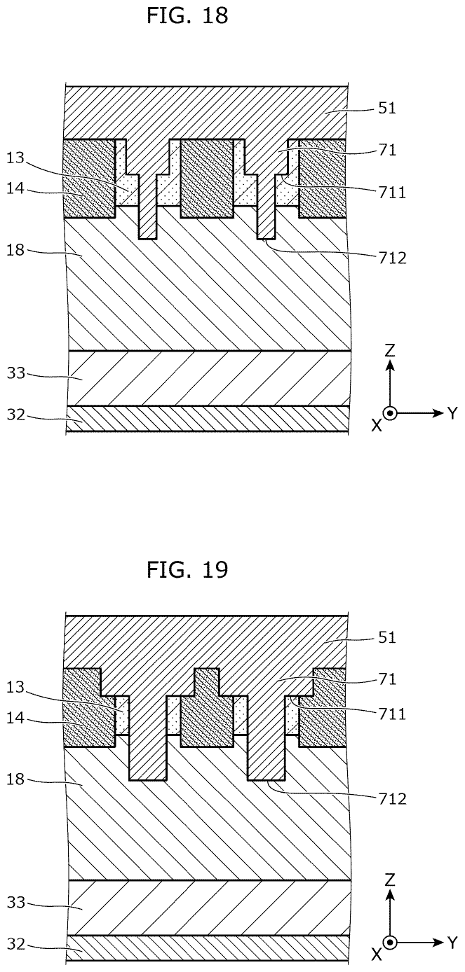

It should be noted that the bottom surface of each of the plurality of first recessed portions 71 may include third bottom surface 711 (see FIGS. 14 to 19 described later) and fourth bottom surface 712 (see FIGS. 14 to 19 described later) below third bottom surface 711. Third bottom surface 711 of each of the plurality of first recessed portions 71 may be above the bottom surface of the one of the plurality of body contact regions 13 that includes corresponding first recessed portion 71.

FIGS. 14 to 19 are enlarged cross-sectional views each schematically illustrating an example of the structure around gate trenches 17 in semiconductor device 1 configured as above.

As such, it is possible to increase the areas of contact between source electrode 51 and body contact regions 13 in body contact regions 13 whose top surfaces are recessed at the plurality of first recessed portions 71.

Thus, it is possible to reduce contact resistance Rbc between source electrode 51 and body contact regions 13 in body contact regions 13 whose top surfaces are recessed at the plurality of first recessed portions 71.

Accordingly, in semiconductor device 1 configured as above, it is possible to further improve the resistance to ASO breakdown.

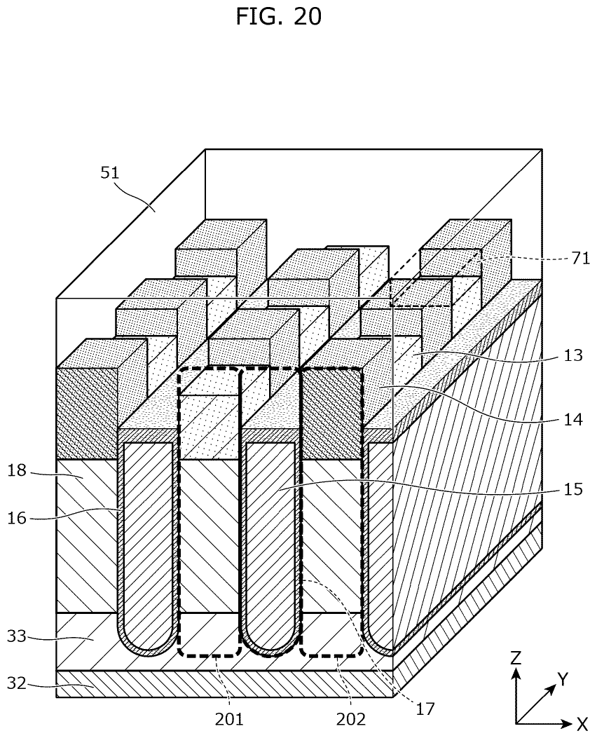

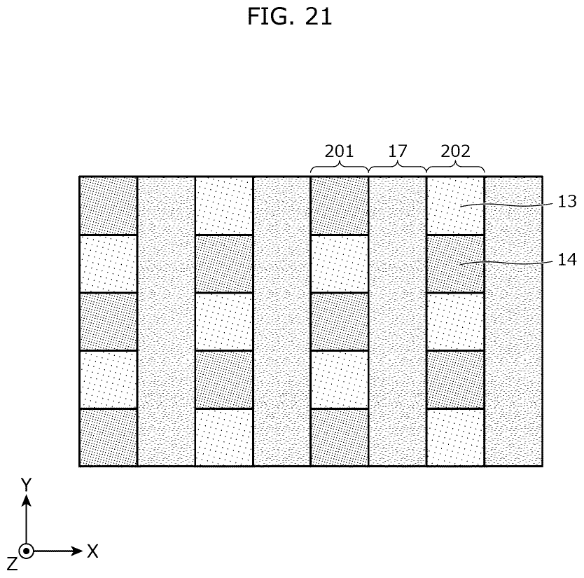

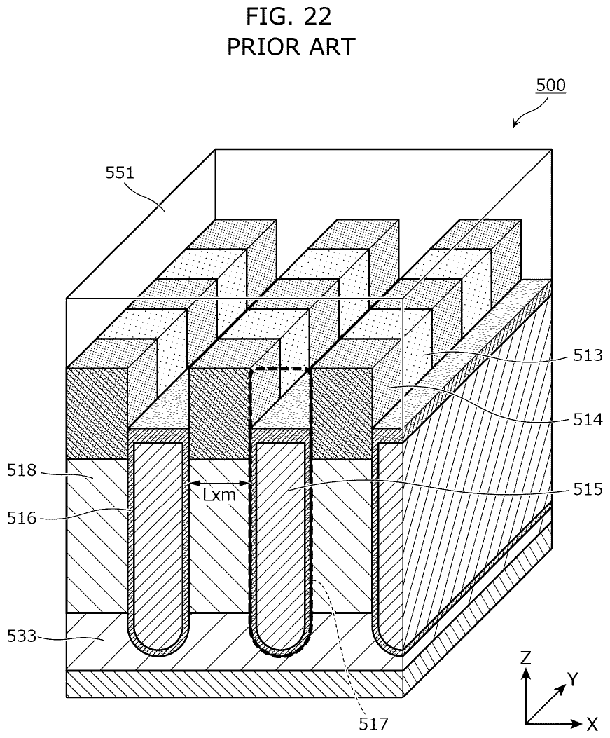

It should be noted that the plurality of mesa portions 20 may include a plurality of first mesa portions 201 (see FIGS. 20 and 21 described later) and a plurality of second mesa portions 202 (see FIGS. 20 and 21 described later) that are arranged alternately one by one in the second direction. The positional phase in the first direction in which the plurality of source regions 14 and the plurality of body contact regions 13 are provided in each of the plurality of first mesa portions 201 may differ from the positional phase in the first direction in which the plurality of source regions 14 and the plurality of body contact regions 13 are provided in each of the plurality of second mesa portions 202.

FIG. 20 is an enlarged cross-sectional perspective view schematically illustrating an example of the structure around gate trenches 17 in semiconductor device 1 configured as above.

In FIG. 20, source electrode 51 is illustrated as if it were transparent. However, in reality, source electrode 51 is not transparent, and the structure behind source electrode 51 is not directly visible through source electrode 51.

FIG. 21 is an enlarged plan view schematically illustrating an example of the structure around gate trenches 17 in semiconductor device 1 described above.

In FIG. 21, illustration of source electrode 51 is omitted as if source electrode 51 were not present. However, in reality, source electrode 51 is present above the illustrated structure in the Z-axis direction in FIG. 21.

It should be noted that the plurality of mesa portions 20 may include a plurality of first mesa portions to a plurality of mth mesa portions arranged sequentially in the second direction, where m is an integer greater than or equal to three. The positional phase in the first direction in which the plurality of source regions 14 and the plurality of body contact regions 13 are provided may differ among the plurality of the first mesa portions to the plurality of mth mesa portions.

### Supplementary Notes

Although the semiconductor device according to one aspect of the present disclosure is described above on the basis of the embodiment, the present disclosure is not limited to the embodiment. The scope of one or more aspects of the present disclosure may also encompass embodiments obtained by adding, to the embodiment, various modifications envisioned by those skilled in the art, and embodiments constructed by combining constituent elements in different variations, as long as the resultant embodiments do not depart from the scope of the present disclosure.

Although only one exemplary embodiment of the present disclosure has been described in detail above, those skilled in the art will readily appreciate that many modifications are possible in the exemplary embodiment without materially departing from the novel teachings and advantages of the present disclosure. Accordingly, all such modifications are intended to be included within the scope of the present disclosure.

### INDUSTRIAL APPLICABILITY

The present disclosure is widely applicable to, for example, semiconductor devices including vertical MOS transistors.

1. A semiconductor device comprising:
a vertical metal-oxide-semiconductor (MOS) transistor;
a semiconductor substrate of a first conductivity type containing a first concentration of an impurity;
a low-concentration impurity layer of the first conductivity type that is provided above and is in contact with the semiconductor substrate, and contains a second concentration of an impurity, the second concentration being lower than the first concentration;
a body region of a second conductivity type that is provided in the low-concentration impurity layer and at a top surface of the low-concentration impurity layer, and contains a third concentration of an impurity, the second conductivity type being different from the first conductivity type;
a plurality of gate trenches extending in a first direction parallel to a top surface of the semiconductor substrate, and arranged at equal intervals in a second direction, the plurality of gate trenches penetrating the body region from the top surface of the low-concentration impurity layer and reaching a portion of the low-concentration impurity layer, the second direction being orthogonal to the first direction and parallel to the top surface of the semiconductor substrate;
a plurality of gate conductors provided in respective ones of the plurality of gate trenches;
a plurality of source regions and a plurality of body contact regions arranged alternately one by one at first intervals in the first direction in each of a plurality of mesa portions sandwiched between the plurality of gate trenches in the second direction, the plurality of source regions being source regions of the first conductivity type provided in the mesa portion and at a top surface of the mesa portion, the plurality of body contact regions being body contact regions of the second conductivity type that are provided in the mesa portion and at the top surface of the mesa portion and contain a fourth concentration of an impurity, the fourth concentration being higher than the third concentration; and
a source electrode of the vertical MOS transistor, wherein
a top surface of each of the plurality of mesa portions includes a plurality of first recessed portions that are recessed at second intervals in the first direction and whose insides are filled with the source electrode, the second intervals being n times the first intervals, where n is an integer greater than or equal to one,
at least a portion of a bottom surface of each of the plurality of first recessed portions is in contact with one of the plurality of body contact regions or the body region,
entire bottom surfaces of the plurality of source regions are above a bottom surface of the body region and in contact with the body region,
entire bottom surfaces of the plurality of body contact regions are above the bottom surface of the body region and in contact with the body region,
entire top surfaces of the plurality of source regions are in contact with the source electrode, and
entire top surfaces of the plurality of body contact regions are in contact with the source electrode.

2. The semiconductor device according to claim 1, wherein
in a plan view of the semiconductor substrate, each of the plurality of first recessed portions is included inside one of the plurality of body contact regions, and
the source electrode is not in contact with any of the plurality source regions inside the plurality of first recessed portions.

3. The semiconductor device according to claim 1, wherein a width of the first recessed portion in the second direction is equal to a width of the plurality of mesa portions in the second direction.

4. The semiconductor device according to claim 1, wherein
the top surface of each of the plurality of mesa portions further includes a plurality of second recessed portions that are recessed at the second intervals in the first direction and whose insides are filled with the source electrode, and
at least a portion of a bottom surface of each of the plurality of second recessed portions is in contact with one of the plurality of body contact regions or the body region.

5. The semiconductor device according to claim 1, wherein
n is one.

6. The semiconductor device according to claim 2, wherein
the bottom surface of each of the plurality of first recessed portions is above a bottom surface of one of the plurality of body contact regions that includes the first recessed portion.

7. The semiconductor device according to claim 2, wherein
the bottom surface of each of the plurality of first recessed portions is below a bottom surface of one of the plurality of body contact regions that includes the first recessed portion.

8. The semiconductor device according to claim 7, wherein
an impurity concentration of the body region is higher in a portion including at least a part of portions in contact with the plurality of first recessed portions than in a remaining portion of the body region.

9. The semiconductor device according to claim 2, wherein
a bottom surface of each of the plurality of body contact regions includes a first bottom surface and a second bottom surface below the first bottom surface, and
the bottom surface of each of the plurality of first recessed portions is below the first bottom surface of one of the plurality of body contact regions that includes the first recessed portion, and above the second bottom surface of the one of the plurality of body contact regions.

10. The semiconductor device according to claim 1, wherein
the bottom surface of each of the plurality of first recessed portions includes a third bottom surface and a fourth bottom surface below the third bottom surface, and
the third bottom surface of each of the plurality of first recessed portions is above a bottom surface of one of the plurality of body contact regions that includes the first recessed portion.

11. The semiconductor device according to claim 1, wherein
the plurality of mesa potions include a plurality of first mesa portions and a plurality of second mesa portions arranged alternately one by one in the second direction, and
a positional phase in the first direction in which the plurality of source regions and the plurality of body contact regions are provided in each of the plurality of first mesa portions differs from a positional phase in the first direction in which the plurality of source regions and the plurality of body contact regions are provided in each of the plurality of second mesa portions.
